(19) United States
(12) Patent Application Publication
(10) Pub. No.: US 2016/0284737 A1
(43) Pub. Date: Sep. 29, 2016

(54) DISPLAY SUBSTRATE, ITS MANUFACTURING METHOD, AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Ying ZHANG, Beijing (CN); Xin DING, Beijing (CN); Fu CHEN, Beijing (CN); Jianhui LIU, Beijing (CN); Kangxu DONG, Beijing (CN); Zuhong LIU, Beijing (CN); Daeoh OH, Beijing (CN); Zhi HOU, Beijing (CN)

(73) Assignees: BOE TECHNOLOGY GROUP CO., LTD., Beijing (CN); HEFEI BOE OPTOELECTRONICS TECHNOLOGY CO., LTD., Hefei, Anhui (CN)

(21) Appl. No.: 14/653,400

(22) PCT Filed: Feb. 27, 2015
(86) PCT No.: PCT/CN2015/073333

§ 371 Date: Jun. 18, 2015

(30) Foreign Application Priority Data
Oct. 29, 2014 (CN) 201410597037.7

(51) Int. Cl. H01L 27/12

(52) U.S. Cl. CPC H01L 27/1218; H01L 27/1262

(57) ABSTRACT

The present disclosure provides a display substrate, its manufacturing method and a display device. The display substrate includes a base substrate, and a film layer pattern arranged on, and in direct contact with, the base substrate. A surface of the base substrate is provided with a groove, and the film layer pattern is arranged within the groove.

### CROSS-REFERENCE TO RELATED APPLICATION

The present application claims a priority of the Chinese patent application No.201410597037.7 filed on Oct. 29, 2014, which is incorporated herein by reference in its entirety.

### TECHNICAL FIELD

The present disclosure relates to the field of display technology, in particular to a display substrate, its manufacturing method and a display device.

### BACKGROUND

During the production of a liquid crystal display panel, it is required to form a thin film transistor (TFT) array substrate including such film layers as a gate electrode, a source electrode, a drain electrode and an active layer. Referring to FIG. 1, which is a schematic view showing a TFT array substrate in the related art, the TFT array substrate includes a base substrate 101, and a gate electrode 102, a gate insulating layer 103, an active layer 104, a source/drain electrode 105, a passivation layer 106 and a pixel electrode 107 arranged on the base substrate 101.

In a process for manufacturing the TFT in the related art, the film layers are arranged on one another at a surface of the flat base substrate 101, and at an edge of a pattern of the gate electrode 102, a segment difference occurs for the subsequent film layers. As a result, it is able to readily cause the breakage of the subsequent film layers at this edge, thereby to cause the electric leakage between the drain electrode and the source/drain electrode, and adversely affect some important performance parameters, such as an off-stage current (I_{off}), of the TFT.

### SUMMARY

An object of the present disclosure is to provide a display substrate, its manufacturing method and a display device, so as to improve the flatness of the entire display substrate, thereby to improve the performance of the display substrate.

In one aspect, the present disclosure provides in embodiments a display substrate, including a base substrate, and a film layer pattern arranged on, and in direct contact with, the base substrate. A surface of the base substrate is provided with a groove, and the film layer pattern is arranged within the groove.

Alternatively, the groove is filled up with the film layer pattern.

Alternatively, the display substrate is a thin film transistor (TFT) array substrate, and the film layer pattern is a gate electrode pattern or an active layer pattern.

Alternatively, the film layer pattern is a gate electrode pattern, and the display substrate includes the base substrate, and a gate electrode, a gate insulating layer, an active layer, a source/drain electrode, a passivation layer and a pixel electrode arranged sequentially on the base substrate. The surface of the base substrate is provided with a groove, and the gate electrode pattern is arranged within the groove.

Alternatively, the base substrate is a glass substrate.

In another aspect, the present disclosure provides in embodiments a method for manufacturing a display substrate, including steps of:

forming a groove at a surface of a base substrate; and

forming a film layer pattern within the groove in such a manner as to fill up the groove.

Alternatively, the step of forming the groove at the surface of the base substrate includes:

applying a photoresist onto the surface of the base substrate;

exposing and developing the photoresist, so as to form a photoresist-reserved region, and a photoresist-unreserved region corresponding to a region of the film layer pattern;

etching the base substrate corresponding to the photoresist-unreserved region by an etching process, so as to form the groove, the groove being of a size identical to the film layer pattern to be formed subsequently; and

removing the photoresist at the photoresist-reserved region.

Alternatively, the step of forming the film layer pattern within the groove in such a manner as to fill up the groove includes:

forming a film layer on the entire base substrate with the groove; the film layer corresponding to the groove being of a thickness greater than a depth of the groove; and

etching the film layer by an etching process, so as to form the film layer pattern arranged within the groove in such a manner as to fill up the groove.

Alternatively, the film layer corresponding to the groove is of a thickness at least 1.2 times the depth of the groove.

Alternatively, the display substrate is a thin film transistor (TFT) array substrate, and the film layer pattern is a gate electrode pattern or an active layer pattern.

In yet another aspect, the present disclosure provides in embodiments a display device including the above-mentioned display substrate.

According to the embodiments of the present disclosure, the surface of the base substrate is provided with the groove, and the film layer pattern of a non-full layer structure and in direct contact with the base substrate is arranged within the groove. As a result, it is able to reduce the occurrence of a segment difference for the subsequent film layers at the film layer pattern, thereby to improve the flatness of the entire display substrate as well as the performance of the display substrate.

### BRIEF DESCRIPTION OF THE DRAWINGS

FIG. 1 is a schematic view showing a TFT array substrate in the related art;

FIG. 2 is a schematic view showing a TFT array substrate according to an embodiment of the present disclosure; and

FIGS. 3-1 to 3-11 are schematic views showing a method for manufacturing the TFT array substrate in FIG. 2.

### DETAILED DESCRIPTION

In order to make the objects, the technical solutions and the advantages of the present disclosure more apparent, the present disclosure will be described hereinafter in conjunction with the drawings and the embodiments.

The present disclosure provides in embodiments a display substrate, including a base substrate, and a film layer pattern arranged on, and in direct contact with, the base substrate. A surface of the base substrate is provided with a groove, and the film layer pattern is arranged within the groove.

In this embodiment, the film layer pattern is of a non-full layer structure.

In the embodiment of the present disclosure, the surface of the base substrate is provided with the groove, and the film layer pattern of a non-full layer structure and in direct contact with the base substrate is arranged within the groove. As a result, it is able to reduce the occurrence of a segment difference for subsequent film layers at the film layer pattern, thereby to improve the flatness of the entire display substrate as well as the performance of the display substrate.

Alternatively, the groove is filled up with the film layer pattern, so as to prevent the occurrence of the segment difference for the subsequent film layers, thereby to further improve the flatness of the entire display substrate as well as the display substrate.

In an embodiment of the present disclosure, the display substrate may be a TFT array substrate. At this time, the film layer pattern may be a gate electrode pattern or an active layer pattern. To be specific, when a TFT in the TFT array substrate is of a bottom-gate structure, the film layer pattern may be the gate electrode pattern, and when the TFT is of a top-gate structure, the film layer pattern may be the active layer pattern.

Alternatively, the base substrate is a glass substrate. Of course, it may also be any other type of the substrate.

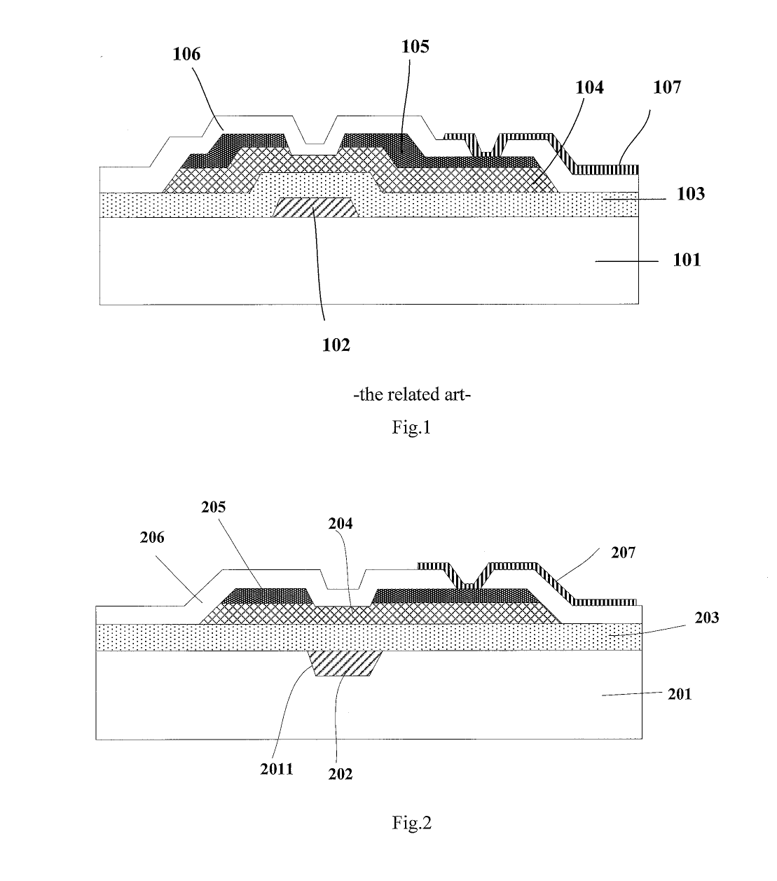

Referring to FIG. 2, which is a schematic view showing the TFT array substrate according to an embodiment of the present disclosure, the TFT array substrate includes a base substrate 201, and a gate electrode 202, a gate insulating layer 203, an active layer 204, a source/drain electrode 205, a passivation layer 206 and a pixel electrode 207 arranged on the base substrate 201. A surface of the base substrate 201 is provided with a groove 2011, and the pattern of the gate electrode 202 is arranged within the groove 2011 in such a manner as to fill up the groove 2011.

The gate electrode 202, the gate insulating layer 203, the active layer 204 and the source/drain electrode 205 form the TFT of a bottom-gate structure.

According to embodiments of the present disclosure, it is able to prevent the occurrence of the segment difference at an edge of the gate electrode 202, thereby to improve the flatness of the entire display substrate as well as the performance of the display substrate.

As shown in FIG. 2, as compared with the TFT array substrate in the related art, the flatness of the entire TFT array substrate according to embodiments of the present disclosure is improved remarkably.

The present disclosure further provides in embodiments a thin film transistor (TFT) array substrate, including a base substrate, and an active layer, a source/drain electrode, a gate insulating layer, a gate electrode, a passivation layer and a pixel electrode arranged on the base substrate. A surface of the base substrate is provided with a groove, and a pattern of the active layer is arranged within the groove in such a manner as to fill up the groove.

The active layer, the source/drain electrode, the gate insulating layer and the gate electrode form a TFT of a top-gate structure.

According to this embodiment of the present disclosure, it is able to prevent the occurrence of the segment difference at an edge of the active layer, thereby to improve the flatness of the entire display substrate as well as the performance of the display substrate.

The present disclosure further provides in embodiments a display device including the display substrate mentioned in any one of the above embodiments.

The present disclosure further provides in embodiments a method for manufacturing a display substrate, including steps of:

Step S1: forming a groove at a surface of a base substrate; and

Step S2: forming a film layer pattern within the groove in such a manner as to fill up the groove.

In this embodiment, the film layer pattern is of a non-full layer structure.

According to embodiments of the present disclosure, the surface of the base substrate is provided with the groove, and the film layer pattern is arranged within the groove in such a manner as to fill up the groove. As a result, it is able to prevent the occurrence of a segment difference for the subsequent film layers at the film layer pattern, thereby to improve the flatness of the entire display substrate as well as the performance of the display substrate.

Alternatively, the step of forming the groove at the surface of the base substrate includes:

Step S11: applying a photoresist onto the surface of the base substrate;

Step S12: exposing and developing the photoresist, so as to form a photoresist-reserved region, and a photoresist-unreserved region corresponding to a region of the film layer pattern;

Step S13: etching the base substrate corresponding to the photoresist-unreserved region by an etching process, so as to form the groove; and

Step S14: removing the photoresist at the photoresist-reserved region.

Alternatively, the step of forming the film layer pattern within the groove in such a manner as to fill up the groove includes the following steps.

Step S21: forming a film layer on the entire base substrate with the groove, the film layer corresponding to the groove being of a thickness greater than a depth of the groove. The film layer corresponding to the groove is provided with a thickness greater than the depth of the groove, so as to level the film layer corresponding to the groove in a better manner, thereby to enable a surface of the film layer pattern to be in flush with the surface of the base substrate.

Step S22: etching the film layer by an etching process, so as to form the film layer pattern arranged within the groove in such a manner as to fill up the groove.

Alternatively, the film layer corresponding to the groove is of a thickness 1.2 times the depth of the groove.

The display substrate may be a TFT array substrate or a color filter substrate. When the display substrate is the TFT array substrate, the film layer pattern may be a gate electrode pattern or an active layer pattern. To be specific, when a TFT of the TFT array substrate is of a bottom-gate structure, the film layer pattern may be the gate electrode pattern, and when the TFT is of a top-gate structure, the film layer pattern may be the active layer pattern.

Alternatively, the base substrate is a glass substrate. Of course, it may also be any other type of the base substrate.

The method will be described hereinafter by taking the TFT array substrate as an example.

FIGS. 3-1 to 3-11 are schematic views showing the method for manufacturing the TFT array substrate in FIG. 2. The method includes the following steps S31-S37.

Step S31: forming the groove 2011 in the glass substrate 201 by etching in accordance with a size of the gate electrode pattern.

To be specific, Step S31 may include:

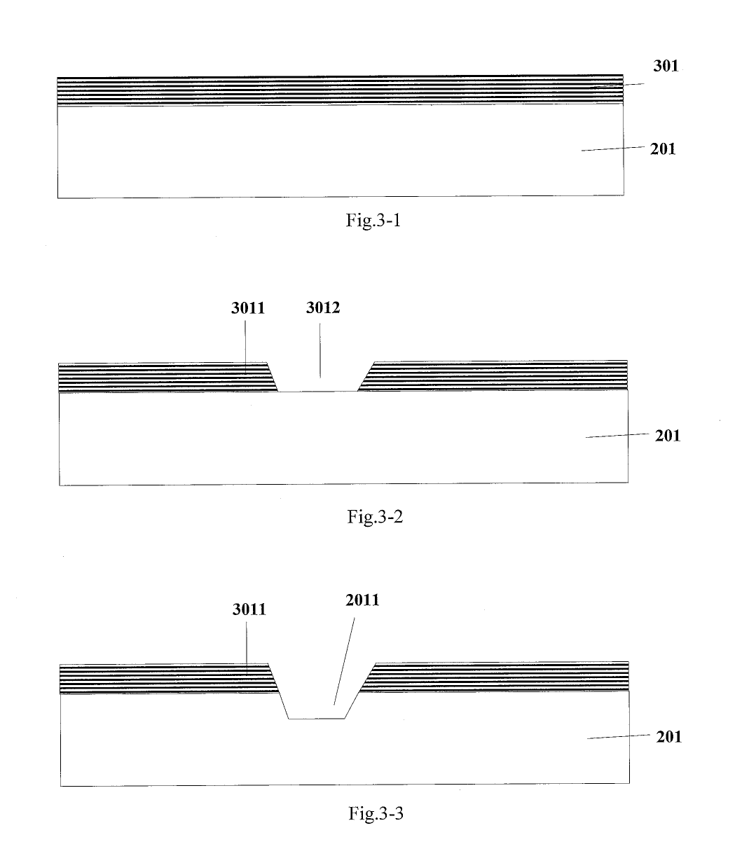

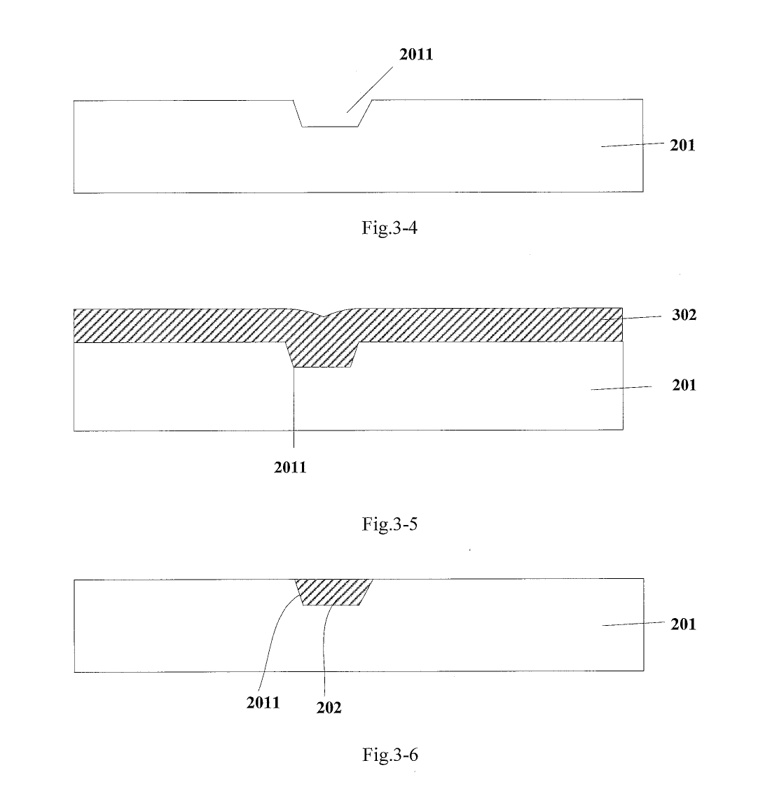

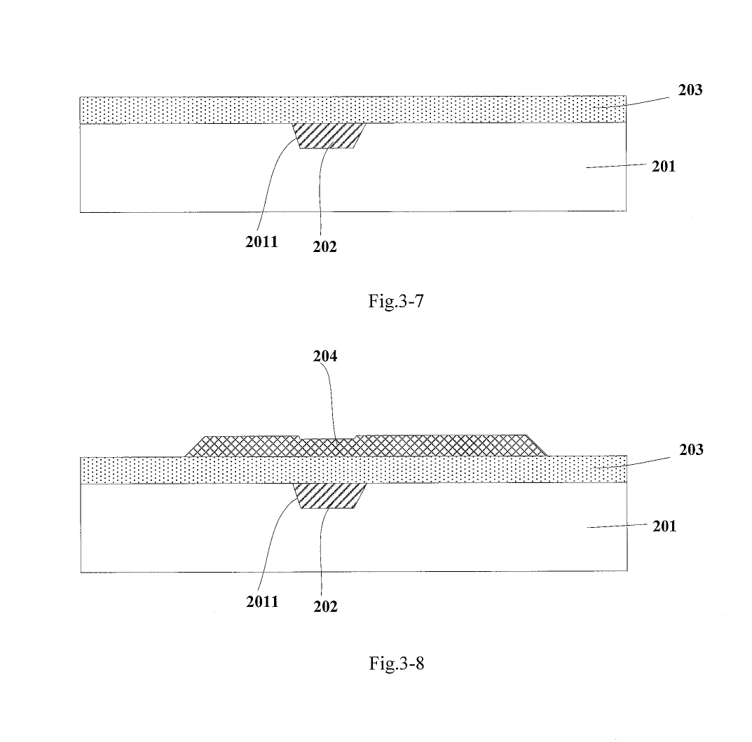

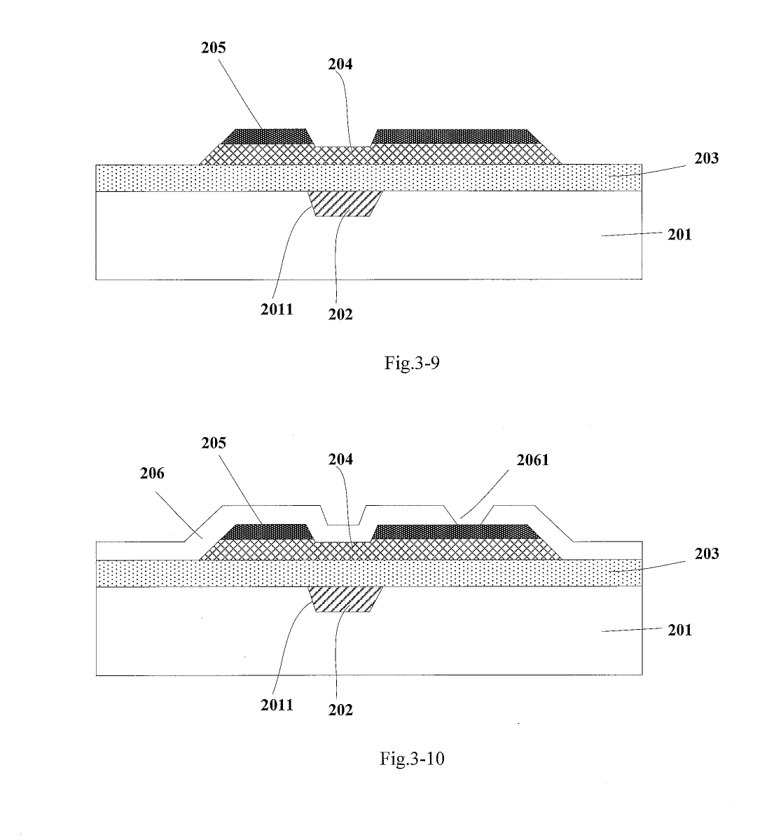

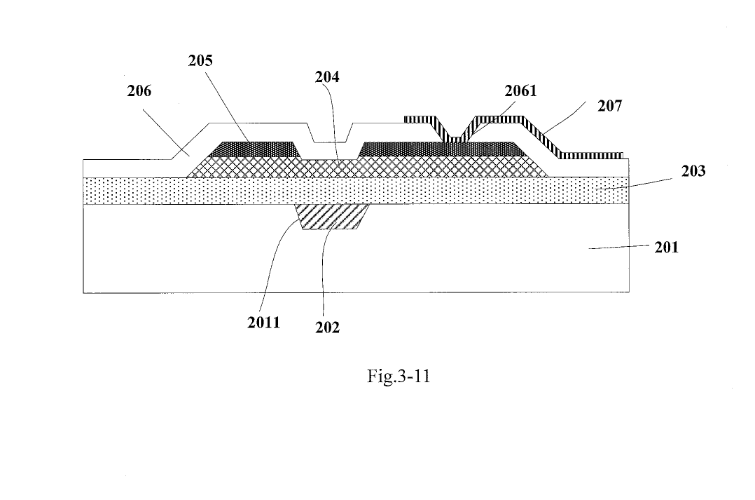

applying a photoresist 301 onto a surface of the glass substrate 201 (FIG. 3-1);

exposing and developing the photoresist 301 so as to form a photoresist-reserved region 3011, and a photoresist-unreserved region 3012 corresponding to a region of the subsequent gate electrode pattern (FIG. 3-2);

etching the glass substrate 201 corresponding to the photoresist-unreserved region 3012 by an etching process, e.g., a dry-etching process or a wet-etching process, so as to form the groove 2011, the groove 2011 being of a size identical to the gate electrode pattern desired to be formed subsequently (FIG. 3-4); and

removing the photoresist at the photoresist-reserved region 3011 by a wet-stripping process or a dry-etching process (FIG. 3-4).

Step S32: forming the pattern of the gate electrode 202 within the groove 2011 in such a manner as to fill up the groove 2011.

To be specific, Step S32 may include:

forming a gate metal film layer 302, which may be made of Mo or Al, on the glass substrate 201 with the groove 2011 by sputtering, the gate metal film layer 301 corresponding to the groove 2011 being of a thickness greater than the depth of the groove 2011 (FIG. 3-5); and

etching the gate metal film layer by an etching process, e.g., an isotropic dry-etching or wet-etching process, at an etching amount slightly greater than a thickness of the gate metal film layer corresponding to the region other than the groove 2011 while not overetching the gate metal film layer within the groove 2011, so as to form the pattern of the gate electrode 202 within the groove 2011 in such a manner as to fill up the groove 2011 (FIG. 3-6).

Step S33: forming the gate insulating layer 203, which may be made of SiO₂ and Si₃N₄, by plasma enhanced chemical vapor deposition (PECVD) (FIG. 3-7).

Step S34: forming the active layer 204 which may contain a semiconductor and a doped semiconductor (FIG. 3-8).

Step S35: forming the source/drain electrode 205, which may be made of Mo or Al, by sputtering (FIG. 3-9).

Step S36: forming the passivation layer 206, which may be made of Si₃N₄, by PECVD, and forming a via-hole 2061 in the passivation layer 206 by etching a photoresist mask, which is formed by photolithography, by a dry-etching or wet-etching process (FIG. 3-10).

Step S37: forming the pixel electrode 207 which is made of indium tin oxide (ITO) and connected to the source or drain electrode through the via-hole 2061 in a lapping manner (FIG. 3-11).

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

1. A display substrate, comprising a base substrate, and a film layer pattern arranged on, and in direct contact with, the base substrate, wherein a surface of the base substrate is provided with a groove, and the film layer pattern is arranged within the groove.

2. The display substrate according to claim 1, wherein the groove is filled up with the film layer pattern.

3. The display substrate according to claim 1, wherein the display substrate is a thin film transistor (TFT) array substrate, and the film layer pattern is a gate electrode pattern or an active layer pattern.

4. The display substrate according to claim 1, wherein the film layer pattern is a gate electrode pattern, and the display substrate comprises the base substrate, and a gate electrode, a gate insulating layer, an active layer, a source/drain electrode, a passivation layer and a pixel electrode arranged sequentially on the base substrate, wherein the surface of the base substrate is provided with a groove, and the gate electrode pattern is arranged within the groove.

5. The display substrate according to claim 1, wherein the base substrate is a glass substrate.

6. A method for manufacturing a display substrate, comprising steps of:
forming a groove at a surface of a base substrate; and
forming a film layer pattern within the groove in such a manner as to fill up the groove.

7. The method according to claim 6, wherein the step of forming the groove at the surface of the base substrate comprises:
applying a photoresist onto the surface of the base substrate;
exposing and developing the photoresist, so as to form a photoresist-reserved region, and a photoresist-unreserved region corresponding to a region of the film layer pattern;
etching the base substrate corresponding to the photoresist-unreserved region by an etching process, so as to form the groove, the groove being of a size identical to the film layer pattern to be formed subsequently; and
removing the photoresist at the photoresist-reserved region.

8. The method according to claim 6, wherein the step of forming the film layer pattern within the groove in such a manner as to fill up the groove comprises:
forming a film layer on the entire base substrate with the groove, the film layer corresponding to the groove being of a thickness greater than a depth of the groove; and
etching the film layer by an etching process, so as to form the film layer pattern arranged within the groove in such a manner as to fill up the groove.

9. The method according to claim 8, wherein the film layer corresponding to the groove is of a thickness at least 1.2 times the depth of the groove.

10. The method according to claim 6, wherein the display substrate is a thin film transistor (TFT) array substrate, and the film layer pattern is a gate electrode pattern or an active layer pattern.

11. A display device comprising the display substrate according to claim 1.

12. The display substrate according to claim 2, wherein the display substrate is a thin film transistor (TFT) array substrate, and the film layer pattern is a gate electrode pattern or an active layer pattern.

13. The display substrate according to claim 2, wherein the film layer pattern is a gate electrode pattern, and the display substrate comprises the base substrate, and a gate electrode, a gate insulating layer, an active layer, a source/drain electrode, a passivation layer and a pixel electrode arranged sequentially on the base substrate, wherein the surface of the base substrate is provided with a groove, and the gate electrode pattern is arranged within the groove.

14. The display substrate according to claim 3, wherein the film layer pattern is a gate electrode pattern, and the display substrate comprises the base substrate, and a gate electrode, a gate insulating layer, an active layer, a source/drain electrode, a passivation layer and a pixel electrode arranged sequentially on the base substrate, wherein the surface of the base substrate is provided with a groove, and the gate electrode pattern is arranged within the groove.

15. The method according to claim 7, wherein the step of forming the film layer pattern within the groove in such a manner as to fill up the groove comprises:
forming a film layer on the entire base substrate with the groove, the film layer corresponding to the groove being of a thickness greater than a depth of the groove; and
etching the film layer by an etching process, so as to form the film layer pattern arranged within the groove in such a manner as to fill up the groove.

16. The method according to claim 7, wherein the display substrate is a thin film transistor (TFT) array substrate, and the film layer pattern is a gate electrode pattern or an active layer pattern.

17. The method according to claim 8, wherein the display substrate is a thin film transistor (TFT) array substrate, and the film layer pattern is a gate electrode pattern or an active layer pattern.

18. The method according to claim 9, wherein the display substrate is a thin film transistor (TFT) array substrate, and the film layer pattern is a gate electrode pattern or an active layer pattern.
